(19) United States
(12) Patent Application Publication
(10) Pub. No.: US 2026/0058849 A1
(43) Pub. Date: Feb. 26, 2026

(54) CONTINUOUS TIME LINEAR EQUALIZER EMPLOYING CURRENT-REUSE AND CURRENT-STEALING ARCHITECTURE

(71) Applicant: QUALCOMM Incorporated, San Diego, CA (US)

(72) Inventors: Timothy Donald GATHMAN, San Diego, CA (US); Nitz SAPUTRA, San Diego, CA (US); Sameer WADHWA, San Diego, CA (US)

(21) Appl. No.: 18/812,354

(22) Filed: Aug. 22, 2024

(51) Int. Cl. H04L 25/03; H03G 1/00; H03G 3/00; H03G 3/30

(52) U.S. Cl. CPC H04L 25/03885; H03G 1/007; H03G 3/004; H03G 3/3052; H03G 2201/10; H03G 2201/603

(57) ABSTRACT

A continuous time linear equalizer (CTLE), comprising: a first transconductance gain circuit configured to amplify an input voltage signal with a first transconductance gain to generate a first current signal; a second transconductance gain circuit configured to amplify the input voltage signal with a second transconductance gain to generate a second current signal, wherein the second transconductance gain circuit is configured to reuse the first current signal to generate the second current signal; and at least one resistor through which the first current signal and the second current signal flow to generate an output voltage signal.

### FIELD

This disclosure relates generally to equalizers for serializer-deserializer (SERDES) data communication links, and in particular, to a continuous time linear equalizer (CTLE) that employs current-reuse and/or current-stealing for configuring its frequency transfer function.

### BACKGROUND

A serializer/deserializer (SERDES) communication link typically includes a set of one or more unidirectional and/or bidirectional data lanes. Each data lane includes a transmitter, a data communication channel, and a receiver. The transmitter is configured to transmit a data signal to the receiver via the data communication channel. The data communication channel typically has a low-pass frequency response or transfer function, which may reduce the high (Nyquist) frequency content at the of the data signal. Accordingly, the receiver typically includes an equalizer to boost the high frequency content of the data signal so as to compensate it for the high frequency losses incurred while propagating through the data communication channel.

### SUMMARY

The following presents a simplified summary of one or more implementations in order to provide a basic understanding of such implementations. This summary is not an extensive overview of all contemplated implementations, and is intended to neither identify key or critical elements of all implementations nor delineate the scope of any or all implementations. Its sole purpose is to present some concepts of one or more implementations in a simplified form as a prelude to the more detailed description that is presented later.

An aspect of the disclosure relates to a continuous time linear equalizer (CTLE). The CTLE includes a first transconductance gain circuit configured to amplify an input voltage signal with a first transconductance gain to generate a first output current signal; a second transconductance gain circuit configured to amplify the input voltage signal with a second transconductance gain to generate a second output current signal, wherein the second transconductance gain circuit is configured to reuse the first output current signal to generate the second output current signal; and at least one resistor through which the first output current signal and the second output current signal flow to generate an output voltage signal.

Another aspect of the disclosure relates to a method of equalizing an input voltage signal. The method includes amplifying an input voltage signal with a first transconductance gain to generate a first current signal; amplifying the input voltage signal with a second transconductance gain to generate a second current signal including reusing the first current signal; and providing the first current signal and the second current signal through at least one resistor to generate an output voltage signal.

To the accomplishment of the foregoing and related ends, the one or more implementations include the features hereinafter fully described and particularly pointed out in the claims. The following description and the annexed drawings set forth in detail certain illustrative aspects of the one or more implementations. These aspects are indicative, however, of but a few of the various ways in which the principles of various implementations may be employed and the description implementations are intended to include all such aspects and their equivalents.

### BRIEF DESCRIPTION OF THE DRAWINGS

FIG. 1 illustrates a block diagram of an example serializer/deserializer (SERDES) communication link in accordance with an aspect of the disclosure.

FIG. 2 illustrates a block diagram of an example continuous time linear equalizer (CTLE) in accordance with another aspect of the disclosure.

FIG. 3 illustrates a schematic diagram of another example continuous time linear equalizer (CTLE) in accordance with another aspect of the disclosure.

FIG. 4A illustrates a block diagram of another example continuous time linear equalizer (CTLE) in accordance with another aspect of the disclosure.

FIG. 4B illustrates a schematic diagram of another example continuous time linear equalizer (CTLE) in accordance with another aspect of the disclosure.

FIG. 5A illustrates a block diagram of another example continuous time linear equalizer (CTLE) in accordance with another aspect of the disclosure.

FIG. 5B illustrates a schematic diagram of another example continuous time linear equalizer (CTLE) in accordance with another aspect of the disclosure.

FIG. 6A illustrates a block diagram of another example continuous time linear equalizer (CTLE) in accordance with another aspect of the disclosure.

FIG. 6B illustrates a schematic diagram of another example continuous time linear equalizer (CTLE) in accordance with another aspect of the disclosure.

FIG. 7 illustrates a graph depicting a transfer function related to example continuous time linear equalizers (CTLEs) described herein in accordance with another aspect of the disclosure.

FIG. 8 illustrates a flow diagram of an example method of equalizing an input voltage signal in accordance with another aspect of the disclosure.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. However, it will be apparent to those skilled in the art that these concepts may be practiced without these specific details. In some instances, well-known structures and components are shown in block diagram form in order to avoid obscuring such concepts. The term “substantially” means that the associated parameter may not be exact as indicated but accounts for some variation due to specified tolerances.

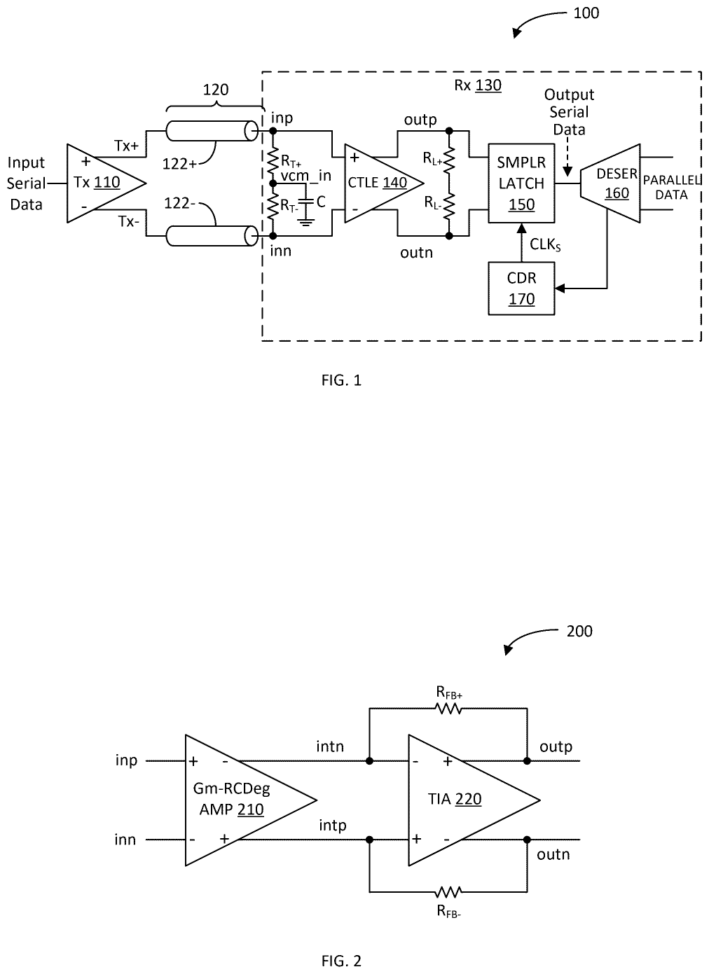

FIG. 1 illustrates a block diagram of an example serializer/deserializer (SERDES) communication link 100 in accordance with an aspect of the disclosure. In this example, the SERDES communication link 100 includes a single unidirectional data lane. However, it shall be understood that the SERDES communication link 100 may include a set of one or more unidirectional data lanes and/or a set of one or more bidirectional data lanes.

The SERDES communication link 100 includes a transmitter (Tx) 110 (e.g., transmit (Tx) driver) coupled to a receiver 130 via a data communication channel 120. The transmitter 110 may be configured to generate a transmit differential signal Tx+/Tx− based on an input serial data signal. The transmit differential signal Tx+/Tx− may be routed to the receiver 130 via differential transmission lines 122+/122− of the data communication channel 120, respectively. The data communication channel 120 typically has a low-pass frequency response or transfer function that reduces high frequency content of signals that propagate therethrough. Accordingly, at the receiver 130, the transmit differential signal Tx+/Tx−, which may be referred to as a received differential signal inp/inn from the perspective of the receiver 130, has its high frequency content reduced due to the data communication channel 120.

The receiver 130, in turn, includes a pair of termination resistors R_{T+} and R_{T-} coupled between the differential transmission lines 122+ and 122− and an input common mode node. An input common mode voltage vcm_in may be generated at the input common mode node based on the input differential signal inp/inn. The termination resistors R_{T+} and R_{T-} reduce signal reflections at the differential input of the receiver 130. The receiver 130 further includes a capacitor C coupled between the input common mode node and a lower voltage rail (e.g., ground) to filter the input common mode voltage vcm_in and provide a proper common-mode termination through resistors R_{T+} and R_{T-}.

The receiver 130 includes a continuous time linear equalizer (CTLE) 140 including a differential input +/− configured to receive the received differential signal inp/inn, respectively. The CTLE 140 is configured to equalize or compensate the received differential signal inp/inn for high frequency losses incurred while propagating via the data communication channel 120 to generate an output differential signal outp/outn across a pair of load resistors R_{L+}/R_{L-}, respectively.

The receiver 130 further includes a sampler/latch 150 configured to sample the output differential signal outp/outn based on a sampling clock signal CLKs to generate an output serial data. Additionally, the receiver 130 includes a deserializer 160 configured to deserialize the output serial data to generate a set of parallel data. Further, the receiver 130 includes a clock and data recovery (CDR) 170 configured to generate the sampling clock signal CLKs based on a feedback signal from the deserializer 160.

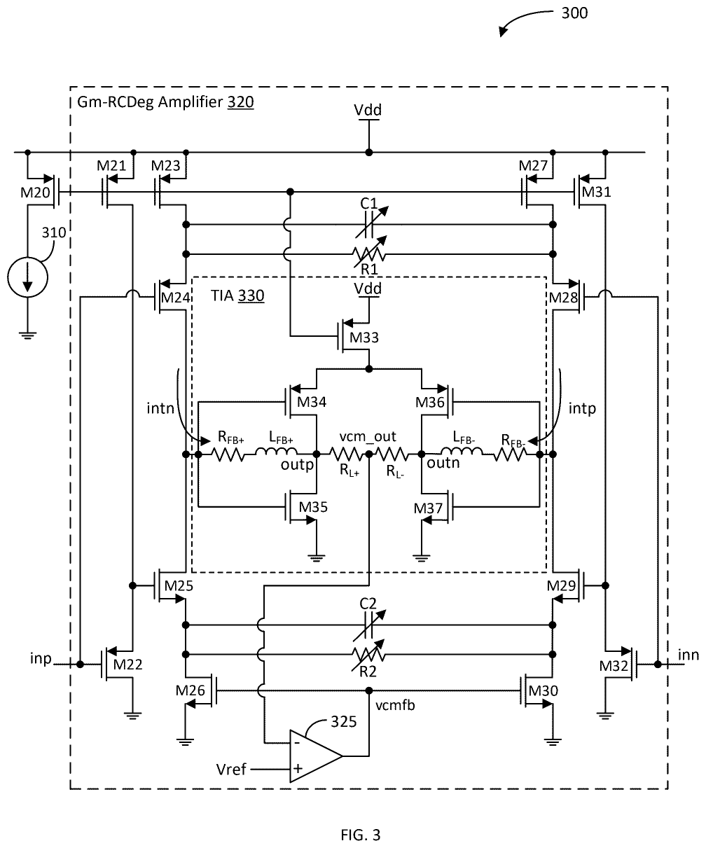

FIG. 2 illustrates a block diagram of an example continuous time linear equalizer (CTLE) 200 in accordance with another aspect of the disclosure. The CTLE 200 may be an example more detailed implementation of the CTLE 140 of SERDES communication link 100. In particular, the CTLE 200 includes a transconductance resistor-capacitor degeneration (Gm-RCDeg) amplifier 210 followed by or cascaded with a transimpedance amplifier (TIA) 220.

The Gm-RCDeg amplifier 210 includes a differential input +/− configured to receive an input differential voltage signal inp/inn, respectively. The Gm-RCDeg amplifier 210 is configured to amplify the input differential voltage signal inp/inn with a transconductance gain Gm to generate an intermediate differential current signal intn/intp at a differential output −/+ of the GM-RCDeg amplifier 210, respectively. As discussed further herein with respect to a more detailed implementation, the Gm-RCDeg amplifier 210 has a programmable transfer function including a low frequency zero and a pair of high frequency poles substantially at the Nyquist frequency associated with the input differential voltage signal inp/inn (e.g., the Nyquist frequency being half the maximum data rate of the input differential voltage signal inp/inn). The transfer function of the Gm-RCDeg amplifier 210 is configured to compensate the input differential voltage signal inp/inn for high frequency losses (e.g., proximate the Nyquist frequency) incurred while propagating via the data communication channel 120 as previously discussed.

The TIA 220 includes a differential input −/+ configured to receive the intermediate differential current signal intn/intp, respectively. The TIA 220 further includes a pair of feedback resistors R_{FB+}/R_{FB-} coupled between a differential output +/− and the differential input −/+ of the TIA 220, respectively. The TIA 220 is configured to amplify the intermediate differential current signal intn/intp with a transimpedance gain REB to generate an output differential voltage signal outp/outn at a differential output +/− of the TIA 220. As discussed in more detail with respect to a more detailed implementation, a pair of inductors may be included in the feedback paths along with the feedback resistors R_{FB+}/R_{FB-} of the TIA 220 to meet bandwidth, linearity, data rate, and headroom requirements.

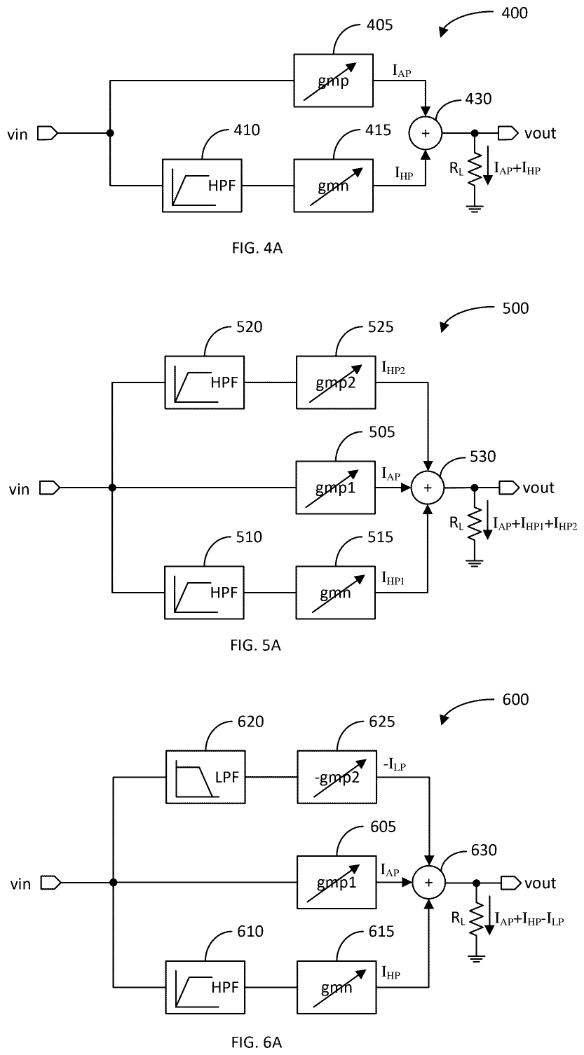

FIG. 3 illustrates a schematic diagram of another example continuous time linear equalizer (CTLE) 300 in accordance with another aspect of the disclosure. The CTLE 300 may be an example more detailed implementation of the CTLE 300 previously discussed. The CTLE 300 includes a transconductance resistor-capacitor degeneration (Gm-RCDeg) amplifier 320 followed by or cascaded with a transimpedance amplifier (TIA) 330. A reference current generated by a reference current source 310 (e.g., a bandgap current source) coupled in series with a p-channel field effect transistor (PFET) M20 between an upper voltage rail Vdd and a lower voltage rail (e.g., ground) may be used to generate substantially temperature-stable currents within the CTLE 300 via current mirror coupling between the PFET M20 and other PFETs within the CTLE 300.

In particular, the Gm-RCDeg Amplifier 320 of the CTLE 300 includes a PFET M21 coupled in series with a PFET M22 between the upper voltage rail Vdd and the lower voltage rail. The PFET M21 includes a gate coupled to a gate of the reference current PFET M20 to effectuate the current mirror coupling thereto. The PFET M22 may serve as one of two input differential FETs including a gate configured to receive a positive component inp of an input differential voltage signal inp/inn.

The Gm-RCDeg Amplifier 320 further includes a PFET M23, a PFET M24, an n-channel field effect transistor (NFET) M25, and an NFET M26 coupled in series between the upper voltage rail Vdd and the lower voltage rail. The PFET M23 includes a gate coupled to the gate of the current reference PFET M20 to effectuate the current mirror coupling thereto. The PFET M24 serves as the other one of the two input differential FETs including a gate configured to receive the positive component inp of the input differential voltage signal inp/inn. The NFET M25 includes a gate coupled to drain and source of the PFETs M21 and M22, respectively.

Additionally, the Gm-RCDeg Amplifier 320 includes a PFET M31 coupled in series with a PFET M32 between the upper voltage rail Vdd and the lower voltage rail. The PFET M31 includes a gate coupled to the gate of the reference current PFET M20 to effectuate the current mirror coupling thereto. The PFET M32 serves as one of two input differential FETs including a gate configured to receive a negative component inn of the input differential voltage signal inp/inn.

The Gm-RCDeg Amplifier 320 further includes a PFET M27, a PFET M28, an NFET M29, and an NFET M30 coupled in series between the upper voltage rail Vdd and the lower voltage rail. The PFET M27 includes a gate coupled to the gate of the current reference PFET M20 to effectuate the current mirror coupling thereto. The PFET M28 serves as the other one of the two input differential FETs including a gate configured to receive the negative component inn of the input differential voltage signal inp/inn. The NFET M29 includes a gate coupled to drain and source of the PFETs M31 and M32, respectively. The NFET M30 includes a gate coupled to a gate of the second NFET M26.

Further, the Gm-RCDeg Amplifier 320 includes a first pair of source degeneration resistor-capacitor R1-C1 coupled in parallel between the source of the PFET M24 and the source of the PFET M28. The first pair of source degeneration resistor-capacitor R1-C1 may have a variable or programmable resistance and capacitance for setting the transfer function or frequency response (e.g., Nyquist frequency peaking) of the Gm-RCDeg Amplifier 320, respectively. Similarly, the Gm-RCDeg Amplifier 320 includes a second pair of source degeneration resistor-capacitor R2-C2 coupled in parallel between the source of the NFET M25 and the source of the NFET M29. The second pair of source degeneration resistor-capacitor R2-C2 may have a variable or programmable resistance and capacitance for setting the transfer function or frequency response (e.g., Nyquist frequency peaking) of the Gm-RCDeg Amplifier 320, respectively.

The TIA 330 includes a PFET M33 coupled between the upper voltage rail Vdd and sources of PFETs M34 and M36, respectively. The PFET M33 includes a gate coupled to the gate of the current reference PFET M20 to effectuate the current mirror coupling thereto. The TIA 330 further includes NFETs M35 and M37, wherein the PFETs M34 and M36 are coupled in series with the NFETs M35 and M37 between the PFET M33 and the lower voltage rail, respectively. The PFET M34 and the NFET M35 include gates coupled to drains of the PFET M24 and NFET M25 of the Gm-RCDeg Amplifier 320, respectively. Similarly, the PFET M36 and the NFET M37 include gates coupled to drains of the PFET M28 and NFET M29 of the Gm-RCDeg Amplifier 320, respectively.

Additionally, the TIA 330 includes a first feedback circuit including a first inductor L_{FB+} coupled in series with a third resistor R_{FB+} between the drains and gates of the PFET M34 and NFET M35. Similarly, the TIA 330 includes a second feedback circuit including a second inductor L_{FB-} coupled in series with a fourth resistor R_{FB-} between the drains and gates of the PFET M36 and NFET M37. Also, the TIA 330 includes first and second load resistors R_{L+} and R_{L-} coupled in series between the drains of PFET M34/NFET M35 and drains of PFET M36/NFET M37, respectively. The TIA 330 is configured to generate an output differential voltage signal outp/outn at the drains of PFET M34/NFET M35 and drains of PFET M36/NFET M37, respectively.

Further, the CTLE 300 includes an output common mode control circuit including a differential amplifier 325 including a first (e.g., negative) input coupled to a node between the load resistors R_{L+} and R_{L-}, a second (e.g., positive) input configured to receive a reference voltage Vref, and an output coupled to the gates of the NFETs M26 and M30, respectively. An output common mode voltage vcm_out based on the output differential signal outp/outn may be generated at the node between the load resistors R_{L+} and R_{L-}. Through negative feedback operation, the differential amplifier 325 is configured to generate an output common mode feedback signal vcmfb for the gates of NFETs M26 and M30 to control the output common mode voltage vcm_out such that it is substantially equal to the reference voltage Vref.

In operation, when the positive input component inp has a higher voltage than the negative input component inn of the input differential voltage signal inp/inn, the PFETs M32 and M28 and NFET M25 are turned on more compared to the PFETs M22 and M24 and NFET M29, respectively. Accordingly, a net current signal intp flows from PFET M23 via the first R1-C1 source degeneration circuit, PFET M28, the TIA 330, NFET M25, the second R2-C2 source degeneration circuit, and NFETs M26 and N30. The first and second R1-C1 and R2-C2 source degeneration circuits boost the high frequency components of the input differential signal inp/inn to achieve peaking at substantially the Nyquist frequency. The net current signal intp flowing from right-to-left through the TIA 330 causes the PFET M34 and NFET M37 to be turned on more compared to PFET M36 and NFET M35; thereby, causing the output positive component outp to have a higher voltage than the output negative component outn of the output differential voltage signal outp/outn. The inductors L_{FB+} and L_{FB-}, each having an impedance that increases with frequency, improve the peaking at substantially the Nyquist frequency.

When the positive input component inp has a lower voltage than the negative input component inn of the input differential voltage signal inp/inn, the PFETs M22 and M24 and NFET M29 are more turned on compared to the PFETs M32 and M28 and NFET M25, respectively. Accordingly, a net current signal intn flows from PFET M27 via the first R1-C1 source degeneration circuit, PFET M24, the TIA 330, NFET M29, the second R2-C2 source degeneration circuit, and NFETs M26 and M30. The first and second R1-C1 and R2-C2 source degeneration circuits boost the high frequency components of the input differential signal inp/inn to achieve peaking at substantially the Nyquist frequency. The net current signal intn flowing from left-to-right through the TIA 330 causes the PFET M36 and NFET M35 to be turned on more compared to PFET M34 and NFET M37; thereby, causing the output positive component outp to have a lower voltage than the output negative component outn of the output differential voltage signal outp/outn. Similarly, the inductors L_{FB+} and L_{FB-}, each having an impedance that increases with frequency, further improve the peaking at substantially the Nyquist frequency.

There are several drawbacks associated with the CTLE 300. For example, the two-stage configuration of the GM-RCDeg amplifier 320 followed by the TIA 330 consumes significant power. Further, the inductors L_{FB+} and L_{FB-} in the TIA 330, which are employed to meet bandwidth, linearity, data rate, and headroom requirements, typically have undesirable consequences, such as producing higher electromagnetic coupling, reducing isolation between components, occupying substantial integrated circuit (IC) footprint, and increasing signal jitter and ringing.

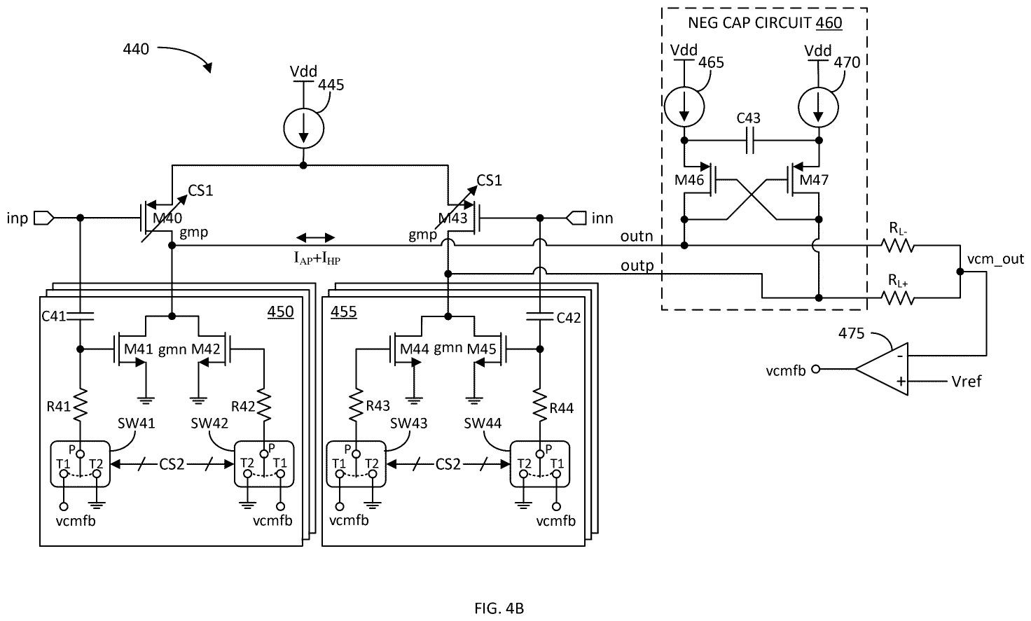

FIG. 4A illustrates a block diagram another example continuous time linear equalizer (CTLE) 400 in accordance with another aspect of the disclosure. The CTLE 400 may employ a single amplification stage, which may result in less power consumption compared to the two-stage implementation of the CTLE 300. Additionally, the CTLE 400 need not employ inductors, which may have the benefits of less electromagnetic coupling, improved component isolation, smaller IC footprint, and lower signal jitter and ringing. As discussed further herein with respect to an example more detailed implementation, the CTLE 400 employs current-reuse to effectuate the control of the transfer function or frequency response of the CTLE 400 to achieve the desired Nyquist peaking.

In particular, the CTLE 400 includes a frequency “all-pass” transconductance gain circuit including a transconductance gain gmp component 405, associated with one or more input PFETs, coupled between an input configured to receive an input voltage signal vin and an output current summing node 430. The transconductance gain gmp component 405 is configured to generate an “all-pass” current signal I_{AP} based on the input voltage signal vin. The frequency “all-pass” means that the frequency response is substantially flat across the operating frequency range of the CTLE 400 (e.g., up to at least the Nyquist frequency). The transconductance gain gmp component 405 may be made programmable or variable for controlling the overall transfer function or frequency response of the CTLE 400, as discussed further herein.

The CTLE 400 further includes a frequency “high-pass” transconductance gain circuit including a high-pass filter (HPF) 410 and a transconductance gain gmn component 415, associated with one or more current-reusing NFETs, coupled between the input and the output current summing node 430. The transconductance gain gmn component 415 is configured to generate a “high-pass” current signal I_{HP} based on the input voltage signal vin. The frequency “high-pass” means that the frequency response exhibits a high-pass frequency response with peaking or pole(s) occurring substantially at the Nyquist frequency. The transconductance gain gmn component 415 may be made programmable or variable for controlling the overall transfer function or frequency response of the CTLE 400, as discussed further herein. Also, as discussed further herein, the high-pass transconductance gain component 415 reuses the current of the all-pass transconductance gain gmp component 405 to effectuate the high-pass transconductance gain gmn.

The output current summing node 430 is configured to sum the all-pass current signal I_{AP} with the high-pass current signal I_{HP} to generate an output current signal I_{AP}+I_{HP} that flows through a load resistor R_{L} to generate an output voltage signal vout. By programming or varying the high-pass path transconductance gain gmn component 415 with respect to the all-pass path transconductance gain gmp component 405 and/or vice-versa, the transfer function or frequency response of the CTLE 400 may be controlled to achieve the desired Nyquist frequency peaking to compensate the input voltage signal vin for high frequency losses incurred while propagating through a data communication channel.

FIG. 4B illustrates a schematic diagram of another example continuous time linear equalizer (CTLE) 440 in accordance with another aspect of the disclosure. The CTLE 440 may be an example more detailed implementation of the CTLE 400 previously discussed. The CTLE 440 includes a current source 445, input differential PFETs M40/M43, and differential high-pass transconductance gain circuits 450/455. The current source 445 is coupled between an upper voltage rail Vdd and sources of the input differential PFETs M40/M43, respectively. The input differential PFETs M40/M43 include gates coupled to a differential input inp/inn of the CTLE 440, respectively. The input differential PFETs M40/M43 include drains coupled to a differential output outn/outp of the CTLE 440, respectively. The input differential PFETs M40 and M43 are configured to amplify an input differential voltage signal (also referred to as “inp/inn”) with a transconductance gain gmp to generate an all-pass current signal I_{AP} flowing between the differential output outp/outn via differential load resistors R_{L+}/R_{L-} to generate an output differential signal outp/outn at the differential output outp/outn, respectively.

The input differential PFETs M40/M43 may have a programmable or variable transconductance gain gmp, which may be controlled by a first control signal (CS1). In particular, the input differential PFETs M40/M43 may include a set of M PFETs M40/M43, which may selectively be coupled in parallel based on the first control signal (CS1), where M is an integer. The higher the number “j” of input differential PFETs selected to be coupled in parallel, the higher is the transconductance gain gmp, where j is an integer equal to or less than M (e.g., j≤M). Conversely, the lower the number “j” of input differential PFETs selected to be coupled in parallel, the lower is the transconductance gain gmp.

The p-side high-pass transconductance gain circuit 450 includes a pair of NFETs M41 and M42 including respective drains coupled to the negative differential output outn (as well as the drain of input differential PFET M40). The pair of NFETs M41 and M42 include respective sources coupled to a lower voltage rail (e.g., ground). The p-side high-pass transconductance gain circuit 450 includes a high-pass filter (HPF) coupled between the gate of the input differential PFET M40 and the gate of NFET M41. More specifically, the HPF includes a capacitor C41 and resistor R41 coupled in series between the positive differential input inp and a switching device SW41 (e.g., which may be implemented structurally and/or functionally as a single pole double throw (SPDT) switching device). The output of the HPF is taken off a node between the capacitor C41 and the resistor R41, which is coupled to the gate of the NFET M41. The SPDT switching device SW41 includes a pole (P) coupled to the resistor R41 of the HPF, a first throw (T1) coupled to an output of a differential amplifier 475 to receive an output common mode feedback signal vcmfb, and a second throw (T2) coupled to the lower voltage rail. The state (e.g., whether the pole (P) is coupled to the first throw (T1) or the second throw (T2)) of the SPDT switching device SW41 is controlled by a second control signal (CS2).

The p-side high-pass transconductance gain circuit 450 further includes a resistor R42 coupled between a gate of the NFET M42 and a switching device SW42, which may also be implemented as a SPDT switching device. Similarly, the SPDT switching device SW42 includes a pole (P) coupled to the resistor R42, a first throw (T1) coupled to the output of the differential amplifier 475 to receive the output common mode feedback signal vcmfb, and a second throw (T2) coupled to the lower voltage rail. The state (e.g., whether the pole (P) is coupled to the first throw (T1) or the second throw (T2)) of the SPDT switching device SW42 is also controlled by the second control signal (CS2). As discussed further herein, the CTLE 440 may include a set of N parallel instantiations or slices of the p-side high-pass transconductance gain circuit 450, where N is an integer.

The n-side high-pass transconductance gain circuit 455 includes a pair of NFETs M44 and M45 including respective drains coupled to the positive differential output outp (as well as the drain of input differential PFET M43). The pair of NFETs M44 and M45 include respective sources coupled to the lower voltage rail. The n-side high-pass transconductance gain circuit 455 further includes a high-pass filter (HPF) coupled between the gate of the input differential PFET M43 and the gate of NFET M45. More specifically, the HPF includes a capacitor C42 and resistor R44 coupled in series between the gate of the negative differential input inn and a switching device SW44 (e.g., which may be implemented structurally and/or functionally as a SPDT switching device). The output of the HPF is taken off a node between the capacitor C42 and the resistor R44, which is coupled to the gate of the NFET M45. The SPDT switching device SW44 includes a pole (P) coupled to the resistor R44 of the HPF, a first throw (T1) coupled to the output of the differential amplifier 475 to receive the output common mode feedback signal vcmfb, and a second throw (T2) coupled to the lower voltage rail. The state (e.g., whether the pole (P) is coupled to the first throw (T1) or the second throw (T2)) of the SPDT switching device SW44 is controlled by the second control signal (CS2).

The n-side high-pass transconductance gain circuit 455 further includes a resistor R43 coupled between a gate of the NFET M44 and a switching device SW43, which may also be implemented as a SPDT switching device. Similarly, the SPDT switching device SW43 includes a pole (P) coupled to the resistor R43, a first throw (T1) coupled to the output of the differential amplifier 475 to receive the output common mode feedback signal vcmfb, and a second throw (T2) coupled to the lower voltage rail. The state (e.g., whether the pole (P) is coupled to the first throw (T1) or the second throw (T2)) of the SPDT switching device SW43 is also controlled by the second control signal (CS2). As discussed further herein, the CTLE 440 may include a set of N parallel instantiations or slices of the n-side high-pass transconductance gain circuit 455.

The NFETs M41 and M45, whose gates are coupled to the outputs of the HPFs C41/R41 and C42/R44 of the p-side/n-side high-pass transconductance gain circuits 450/455 are configured to amplify the high frequency components (e.g., substantially at the Nyquist frequency) of the input differential signal inp/inn with an effective high-pass transconductance gain gmn to generate a high-pass current signal I_{HP} flowing between the positive and negative differential outputs outp/outn via load resistors R_{L+}/R_{L-}, respectively. The effective high-pass transconductance gain gmn depends on how many of the NFETs M41 and M45 are enabled in the set of N parallel slices of the p-side/n-side high-pass transconductance gain circuits 450/455.

The disabling/enabling of the NFETs M41 and M45 depends on the states of the SPDT switching devices SW41-SW44, which serve as a control circuit. For example, the NFETs M41 and M45 are disabled if the SPDT switching devices SW41 and SW44 are configured to have their poles (P) coupled to their second throws (T2), respectively. In this configuration, the SPDT switching devices SW41 and SW44 couple the gates of NFETs M41 and M45 to the lower voltage rail (e.g., ground) to effectively turn off or disable the NFETs M41 and M45. When the NFETs M41 and M45 are disabled, the corresponding NFETs M42 and M44 are enabled via the SPDT switching devices SW42 and SW43 being configured to have their poles (P) coupled to their first throws (T1), respectively. In this configuration, the SPDT switching devices SW42 and SW43 couple the gates of NFETs M42 and M44 to the output of the differential amplifier 475 to receive the output common mode feedback signal vcmfb. This configures the NFETs M42 and M44 as substantially constant current sources.

Similarly, the NFETs M41 and M45 are enabled if the SPDT switching devices SW41 and SW44 are configured to have their poles (P) coupled to their first throws (T1), respectively. In this configuration, the SPDT switching devices SW41 and SW44 couple the gates of NFETs M41 and M45 to the output of the differential amplifier 475 to receive the output common mode feedback signal vcmfb. This configures the NFETs M41 and M45 as transconductance gain gmn components. When the NFETs M41 and M45 are enabled, the corresponding NFETs M42 and M44 are disabled via the SPDT switching devices SW42 and SW43 being configured to have their poles (P) coupled to their second throws (T2), respectively. In this configuration, the SPDT switching devices SW42 and SW43 couple the gates of NFETs M42 and M44 to the lower voltage rail (e.g., ground) to effectively turn off or disable the NFETs M42 and M44.

The degree of Nyquist peaking in the transfer function or frequency response of the CTLE 440 depends on how many of the NFETs M41 and M44 are enabled in the set of N parallel slices of the p-side/n-side high-pass transconductance gain circuits 450/455. For example, if all of the N parallel slices of the p-side/n-side high-pass transconductance gain circuits 450/455 are disabled (e.g., by disabling the corresponding NFETs M41/M45 and enabling the corresponding NFETs M42/M44), the CTLE 440 may have a substantially flat transfer function or frequency response dictated by the all-pass transconductance gain gmp of the input differential PFETs M40/M43. In such case, the differential current signal generated by the CTLE 440 is substantially the all-pass differential current signal I_{AP} (e.g., where the high-pass differential current signal I_{HP} may be substantially zero (0)).

If all of the N parallel slices of the p-side/n-side high-pass transconductance gain circuits 450/455 are enabled (e.g., by enabling the corresponding NFETs M41/M45 and disabling the corresponding NFETs M42/M44), the CTLE 440 has a transfer function or frequency response with a maximum Nyquist peaking dictated by the maximum effective high-pass transconductance gain gmn and the all-pass transconductance gain gmp of the input differential PFETs M40/M43. In such case, the differential current signal generated by the CTLE 440 may be characterized by a sum of the all-pass differential current signal I_{AP} and the maximum high-pass differential current signal I_{HP,max} (e.g., I_{AP}+I_{HP,max}).

Accordingly, the degree of Nyquist peaking in the transfer function or frequency response of the CTLE 440 depends on the number “k” of NFETs M41/M45 that are enabled and NFETs M42/M44 that are disabled versus the number (N−k) of NFETs M41/M45 that are disabled and NFETs M42/M44 that are enabled, where k is also an integer equal to or less than N (e.g., k≤N). Thus, if relatively high Nyquist peaking is desired, set k to be at or relatively close to N; if relatively low Nyquist peaking is desired, set k to be relatively close to zero (0); and if medium Nyquist peaking is desired, set k to be around half of N (e.g., k˜N/2). As an example, the CTLE 440 may include a set of N=12 parallel slices of the p-side/n-side high-pass transconductance gain circuits 450/455 to provide a set of 12 progressive levels of Nyquist peaking in the transfer function or frequency response of the CTLE 440.

The p-side/n-side high-pass transconductance gain circuits 450/455 reuse the current that has flowed through the input differential PFETs M43/M40 to effectuate the high-pass transconductance gain gmn, respectively. For example, if the positive component inp has a voltage higher than the negative component inn of the input differential voltage signal inp/inn, the input differential PFET M43 is turned on greater than the input differential PFET M40. Thus, the net all-pass differential current I_{AP} flows from the input differential PFET M43 to the NFETs M41 of the k slices of the p-side high-pass transconductance gain circuit 450 via the positive differential output outp, differential load resistors R_{L+}/R_{L-} and the negative differential output outn. As the high frequency content of the higher voltage positive component inp of the input differential signal inp/inn is applied to the gate of k NFETs M41 via the HPF C41/R41, the k NFETs M41 reuse the all-pass differential current I_{AP} to generate the net high-pass differential current I_{HP} also flowing from the input differential PFET M43 to the NFETs M41 of the k slices of the p-side high-pass transconductance gain circuit 450 via the positive differential output outp, differential load resistors R_{L+}/R_{L-} and the negative differential output outn.

Similarly, if the positive component inp has a voltage lower than the negative component inn of the input differential voltage signal inp/inn, the input differential PFET M40 is turned on greater than the input differential PFET M43. Thus, the net all-pass differential current I_{AP} flows from the PFET M40 to the NFETs M45 of the k slices of the n-side high-pass transconductance gain circuit 455 via the negative differential output outn, the differential load resistors R_{L-}/R_{L+}, and the positive differential output outp. As the high frequency content of the higher voltage negative component inn of the input differential signal inp/inn is applied to the gate of k NFETs M45 via the HPF C42/R44, the k NFETs M45 reuse the all-pass differential current I_{AP} to generate the net high-pass differential current I_{HP} also flowing from the input differential PFET M40 to the NFETs M45 of the k slices of the n-side high-pass transconductance gain circuit 455 via the negative differential output outn, differential load resistors R_{L-}/R_{L+} and the positive differential output outp.

As discussed, the differential current signal I_{AP}+I_{HP} generated by the CTLE 440 flows through the differential load resistors R_{L+}/R_{L-} to generate an output differential voltage signal outp/outn at the differential output outp/outn of the CTLE 440, respectively. With each of the differential load resistors R_{L+}/R_{L-} set to substantially the same resistance, the output differential voltage signal outp/outn produces an output common mode voltage vcm_out at an output common mode node between the load resistors R_{L+}/R_{L-}. The differential amplifier 475 includes a first (e.g., negative) input coupled to the output common mode node to receive the output common mode voltage vcm_out. The differential amplifier 475 includes a second (e.g., positive) input configured to receive a substantially constant reference voltage (e.g., a bandgap reference voltage). Through negative feedback, the differential amplifier 475 is configured to generate the output common mode feedback signal vcmfb to force the output common mode voltage vcm_out to be substantially equal to the reference voltage Vref.

The CTLE 440 may optionally include a negative capacitance circuit 460 configured to substantially cancel out parasitic capacitance present at the differential output outp/outn of the CTLE 440. In this regard, the negative capacitance circuit 460 includes a first current source 465 coupled in series with an NFET M46 between the upper voltage rail Vdd and the negative differential output outn. Similarly, the negative capacitance circuit 460 includes a second current source 470 coupled in series with an NFET M47 between the upper voltage rail Vdd and the positive differential output outp. The gate of the NFET M46 is coupled to the positive differential output outp, and the gate of the NFET M47 is coupled to the negative differential output node outn. A capacitor C43 is coupled between the respective sources of the NFETs M46 and M47.

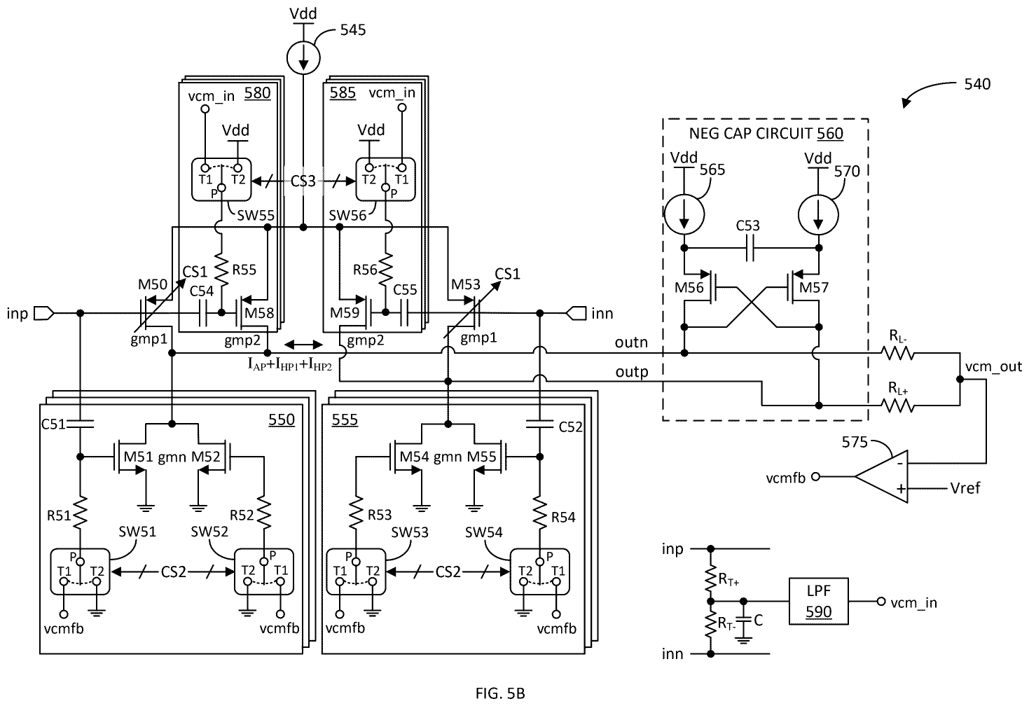

FIG. 5A illustrates a block diagram of another example continuous time linear equalizer (CTLE) 500 in accordance with another aspect of the disclosure. Similarly, the CTLE 500 may employ a single amplification stage, which may result in less power consumption compared to the two-stage implementation of the CTLE 300. Similar to CTLE 440, the CTLE 500 need not include inductors, which may have the benefits of less electromagnetic coupling, improved component isolation, smaller IC footprint, and lower signal jitter and ringing. Also similar to CTLE 440, the CTLE 500 employs current-reuse to effectuate the control of the transfer function or frequency response of the CTLE 500 to achieve the Nyquist peaking as desired. Further, as discussed in more detail herein, the CTLE 500 also employs current stealing to achieve additional Nyquist peaking if desired.

In particular, the CTLE 500 includes a frequency “all-pass” transconductance gain circuit including a transconductance gain gmp1 component 505, associated with a first set of one or more PFETs, coupled between an input configured to receive an input voltage signal vin and an output current summing node 530. The transconductance gain gmp1 component 505 is configured to generate an “all-pass” current signal component I_{AP} based on the input voltage signal vin. Similarly, the frequency “all-pass” means that the frequency response is substantially flat across the operating frequency range of the CTLE 500 (e.g., up to at least the Nyquist frequency). The transconductance gain gmp1 component 505 may be made programmable or variable for controlling the overall transfer function or frequency response of the CTLE 500.

The CTLE 500 further includes a first frequency “high-pass” transconductance gain circuit including a high-pass filter (HPF) 510 and a transconductance gain gmn component 515, associated with one or more NFETs, coupled between the input and the output current summing node 530. The transconductance gain gmn component 515 is configured to generate a first “high-pass” current signal component I_{HP1} based on the input voltage signal vin. The frequency “high-pass” means that the frequency response exhibits a high-pass frequency response with peaking or pole(s) occurring substantially at the Nyquist frequency. The transconductance gain gmn component 515 may be made programmable or variable for controlling the overall transfer function or frequency response of the CTLE 500. Similar to CTLE 500, the high-pass transconductance gain gmn component 515 reuses the current of the all-pass transconductance gain gmp1 component 505 to effectuate the high-pass transconductance gain gmn.

The CTLE 500 further includes a second frequency “high-pass” transconductance circuit including a high-pass filter (HPF) 520 and a transconductance gain gmp2 component 525, associated with a second set of one or more PFETs, coupled between the input and the output current summing node 530. The transconductance gain gmp2 component 525 is configured to generate a second “high-pass” current signal component I_{HP2} based on the input voltage signal vin. Similarly, the frequency “high-pass” means that the frequency response exhibits a high-pass frequency response with peaking or pole(s) substantially at the Nyquist frequency. The transconductance gain gmp2 component 525 may be made programmable or variable for controlling the overall transfer function or frequency response of the CTLE 500. As discussed in more detail herein, the high-pass transconductance gain component 525 steals current from the all-pass transconductance gain gmp1 component 505 to effectuate the second high-pass transconductance gain gmp2.

The output current summing node 530 is configured to sum the all-pass current signal I_{AP} with the first high-pass current signal I_{HP1} and the second high-pass current signal I_{HP2} to generate an output current I_{AP}+I_{HP1}+I_{HP2} that flows through a load resistor R_{L} to generate an output voltage vout. By programming or varying the first and second high-pass transconductance gains gmn and gmp2 with respect to the all-pass path transconductance gain gmp1 and/or vice-versa, the transfer function or frequency response of the CTLE 500 may be controlled to achieve the desired Nyquist frequency peaking to compensate the input voltage signal vin for high frequency losses incurred while propagating via a data communication channel.

FIG. 5B illustrates a schematic diagram another example continuous time linear equalizer (CTLE) 540 in accordance with another aspect of the disclosure. The CTLE 540 is similar to CTLE 440, including many of the same/similar elements as indicated by the same reference indicators/numbers with the most significant digit being a “5” in CTLE 540 instead of a “4” in CTLE 440. For instance, the CTLE 540 includes input differential PFETs M50/M53, first p-side/n-side high-pass transconductance circuits 550 and 555, load resistors R_{L+} and R_{L-}, differential amplifier 575, and optional negative capacitance circuit 560 in the same/similar arrangement as the corresponding components in CTLE 440.

As previously discussed, the input differential PFETs M50/M53 are configured to amplify an input differential signal inp/inn with an all-pass transconductance gain gmp1 to generate an all-pass differential current signal I_{AP}. Similar to input differential PFETs M50/M53, the all-pass transconductance gain gmp1 may be programmable and controlled by a first control signal (CS1) (e.g., by enabling j of a set of M parallel input differential PFETs M50/M53). The first p-side/n-side high-pass transconductance circuits 550/555 may be implemented similar to p-side/n-side high-pass transconductance circuits 450/455 previously discussed. As such, the first p-side/n-side high-pass transconductance circuits 550/555 may be configured to amplify the input differential signal inp/inn with a first high-pass transconductance gain gmn to generate a first high-pass differential current signal I_{HP1}. Similarly, the first high-pass transconductance gain gmn may be programmable based on a second control signal (CS2) (e.g., by enabling k of a set of N parallel slices of the first p-side/n-side high-pass transconductance circuits 550/555).

The CTLE 540 further includes second p-side/n-side high-pass transconductance circuits 580 and 585. As discussed further herein, the second p-side/n-side high-pass transconductance circuits 580 and 585 steal current from the input differential PFETs M50 and M53 to effectuate a second high-pass transconductance gain gmp2 to generate a second differential high-pass current signal I_{HP2} based on the input differential signal inp/inn, respectively. The second high-pass transconductance gain gmp2 may be programmable based on a third control signal (CS3). As discussed further herein, the second p-side/n-side high-pass transconductance circuits 580 and 585 may be activated/enabled after maximum Nyquist peaking has been exhausted using the N slices of the first p-side/n-side high-pass transconductance circuits 550 and 555.

The second p-side high-pass transconductance circuit 580 includes a PFET M58, a high-pass filter (HPF) including capacitor C54 and resistor R55, and a switching device SW55. The PFET M58 is coupled between the current source 545 and the n-side differential output outn of the CTLE 540. The HPF is coupled between the gate of the p-side input differential PFET M50 and a gate of the PFET M58. More specifically, the capacitor C54 and resistor R55 of the HPF are coupled in series between the gate of the p-side input differential PFET M50 and the switching device SW55, wherein an output node of the HPF, situated between the capacitor C54 and resistor R55, is coupled to the gate of PFET M58. The switching device SW55 may be implemented as a SPDT switching device including a pole (P) coupled to the resistor R55, a first throw (T1) coupled to an output of a low-pass filter (LPF) 590 to receive an input common mode voltage vcm_in therefrom, and a second throw (T2) coupled to the upper voltage rail Vdd. The state (e.g., whether the pole (P) is coupled to the first throw (T1) or the second throw (T2)) of the SPDT switching device SW55 is controlled by the third control signal (CS3).

The CTLE 540 further includes differential termination resistors R_{T+}/R_{T-} coupled in series between the differential input inp/inn, respectively. A capacitor C is coupled between an input common mode node between termination resistors R_{T+} and R_{T-} and the lower voltage rail (e.g., ground). The LPF 590 includes an input coupled to the input common mode node between termination resistors R_{T+} and R_{T-}, and configured to generate the input common mode voltage vcm_in.

As mentioned, the CTLE 540 may include a set of P parallel instantiations or slices of the second p-side high-pass transconductance gain circuits 580, where P is an integer. The switching device SW55, operating as a control circuit, is configured via the third control signal CS3 to couple the pole (P) to the first throw (T1) to disable the corresponding slice of the second p-side high-pass transconductance circuit 580 by coupling the upper voltage rail (or applying) Vdd to the gate of the PFET M58. Similarly, the switching device SW55 is configured, via the third control signal CS3, to couple the pole (P) to the second throw (T2) to enable the corresponding slice of the second p-side high-pass transconductance circuit 580 by coupling the output of the LPF 590 (or applying vcm_in) to the gate of the PFET M58.

The second n-side high-pass transconductance circuit 585 includes a PFET M59, a high-pass filter (HPF) including capacitor C55 and resistor R56, and a switching device SW56. The PFET M59 is coupled between the current source 545 and the p-side differential output outp of the CTLE 540. The HPF is coupled between the gate of the n-side input differential PFET M53 and a gate of the PFET M59. More specifically, the capacitor C55 and resistor R56 of the HPF are coupled in series between the gate of the n-side input differential PFET M53 and the switching device SW56, wherein an output node of the HPF, situated between the capacitor C55 and resistor R56, is coupled to a gate of PFET M59. The switching device SW56 may be implemented as a SPDT switching device including a pole (P) coupled to the resistor R56, a first throw (T1) coupled to the output of the LPF 590 to receive the input common mode voltage vcm_in therefrom, and a second throw (T2) coupled to the upper voltage rail Vdd. The state (e.g., whether the pole (P) is coupled to the first throw (T1) or the second throw (T2)) of the SPDT switching device SW56 is controlled by the third control signal (CS3).

As mentioned, the CTLE 540 may include a set of P parallel instantiations or slices of the second n-side high-pass transconductance gain circuits 585, where P is an integer. The switching device SW55, operating as a control circuit, is configured via the third control signal CS3 to couple the pole (P) to the first throw (T1) to disable the corresponding slice of the second n-side high-pass transconductance circuit 585 by coupling the upper voltage rail (or applying) Vdd to the gate of the PFET M59. Similarly, the switching device SW55 is configured, via the third control signal CS3, to couple the pole (P) to the second throw (T2) to enable the corresponding slice of the second n-side high-pass transconductance circuit 585 by coupling the output of the LPF 590 (or applying vcm_in) to the gate of the PFET M59.

The degree of Nyquist peaking provided by the CTLE 540 depends on how many of the PFETs M58 and M59 are enabled in the set of P slices of the second p-side/n-side high-pass transconductance gain circuits 580/585. For example, if all of the P slices of the second p-side/n-side high-pass transconductance gain circuits 580/585 are configured to have the PFETs M58/M59 disabled, the CTLE 540 has a transfer function or frequency response dictated by the all-pass transconductance gain gmp of the input differential PFETs M40 and M43 and the first high-pass transconductance gain gmn dictated by the first p-side/n-side high-pass transconductance circuits 550/555. In such case, the current signal generated by the CTLE 540 is substantially the current signal I_{AP}+I_{HP1} (e.g., the second high-pass current signal I_{HP2} may be substantially zero (0)).

If all of the P slices of the second p-side/n-side high-pass transconductance gain circuits 580 and 585 are configured to have the PFETs M58/M59 enabled, the CTLE 540 has a transfer function or frequency response with a maximum Nyquist peaking with respect to the low frequency zero dictated by the maximum effective second high-pass transconductance gain gmp2, the maximum effective first high-pass transconductance gain of the first p-side/n-side high-pass transconductance gain circuits 550/555, and the all-pass transconductance gain gmp1 of the input differential PFETs M50 and M53. In such case, the current signal generated by the CTLE 540 may be characterized by a sum of the all-pass current signal I_{AP}, the maximum first high-pass current I_{HP1,max}, and the maximum second high-pass current signal I_{HP2,max} (e.g., I_{AP}+I_{HP1,max}+I_{HP2,max}).

Accordingly, the degree of Nyquist peaking in the transfer function or frequency response of the CTLE 540 depends on the number 1 of P PFETs M58/M59 that are enabled, where 1 is also an integer. Thus, if higher Nyquist peaking with respect to the low frequency zero that may be achieved by the p-side/n-side high-pass transconductance circuits 550/555 is desired, set 1 as desired above zero (0); and if Nyquist peaking as achieved by the first p-side/n-side high-pass transconductance circuits 550/555 is satisfactory, set k to be to zero (0). As an example, the CTLE 540 may include a set of P=12 slices of the second p-side and n-side high-pass transconductance gain circuits 580 and 585 to provide a set of 12 progressive levels of additional Nyquist peaking in the transfer function or frequency response of the CTLE 540 above what can be achieved by the first p-side/n-side high-pass transconductance circuits 550/555.

As the current source 545 feeds current to input differential PFETs M50 and M53, and the PFETs M58 and M59 of the second p-side and n-side high-pass transconductance gain circuits 580 and 585, the enabled second p-side and n-side high-pass transconductance gain circuits 580 and 585 steal current that would otherwise be used by the input differential PFETs M50 and M53. The second p-side and n-side high-pass transconductance gain circuits 580 and 585 are configured to use the “stolen” current to effectuate the high-pass transconductance gain gmp2 to provide additional peaking at the Nyquist frequency. Accordingly, the stealing of current from the input differential PFETs M50 and M53 reduces the all-pass transconductance gain gmp1. Thus, the effect of the second p-side and n-side high-pass transconductance gain circuits 580 and 585 is to reduce the lower frequency zero portion of the transfer function or frequency response of the CTLE 540 based on the number 1 of the second p-side and n-side high-pass transconductance gain circuits 580 and 585, while providing additional Nyquist frequency peaking.

For example, if the positive component inp has a voltage higher than the negative component inn of the input differential voltage signal inp/inn, the input differential PFET M53 is turned on greater than the input differential PFET M50. Thus, the reduced (by stealing) all-pass current I_{AP} flows from the PFET M53 via load resistors R_{L+} and R_{L-} to the NFETs M51 of the N slices of the first p-side high-pass transconductance gain circuit 550. As the high frequency content of the higher voltage positive component inp of the input differential signal inp/inn is applied to the gate of the N NFETs M51 via the corresponding N HPFs C51/R51, the first high-pass differential current I_{HP1} also flows from the input differential PFET M53 to the NFETs M51 of the N slices of the first p-side high-pass transconductance gain circuit 550 via the positive differential output outp, differential load resistors R_{L+}/R_{L-} and the negative differential output outn. Similarly, the stolen HPF current I_{HP2} flows from PFETs M59 of the 1 slices of the second n-side high-pass transconductance circuit 585 via load resistors R_{L+} and R_{L-} to the NFETs M51 of the N slice of the first p-side high-pass transconductance gain circuit 550.

Similarly, if the positive component inp has a voltage lower than the negative component inn of the input differential voltage signal inp/inn, the input differential PFET M50 is turned on greater than the input differential PFET M53. Thus, the reduced (by stealing) all-pass current I_{AP} flows from the PFET M50 via load resistors R_{L-} and R_{L+} to the NFETs M55 of the N slices of the first n-side high-pass transconductance gain circuit 555. As the high frequency content of the higher voltage negative component inn of the input differential signal inp/inn is applied to the gate of N NFETs M55 via the corresponding N HPFs C52/R54, the first high-pass differential current I_{HP1} flows from the input differential PFET M50 to the NFETs M55 of the N slices of the first n-side high-pass transconductance gain circuits 555 via the negative differential output outn, differential load resistors R_{L-}/R_{L+} and the positive differential output outp. Similarly, the stolen HPF current I_{HP2} flows from PFETs M58 of the 1 slices of the second p-side high-pass transconductance circuit 580 via load resistors R_{L-} and R_{L+} to the NFETs M55 of the N slices of the first n-side high-pass transconductance gain circuit 555.

The current signal I_{AP}+I_{HP1}+I_{HP2} generated by the CTLE 540 flows through the load resistors R_{L+} and R_{L-} to generate an output differential voltage signal outp/outn at the drains of the input differential PFETs M53 and M50, respectively. With the load resistors R_{L+} and R_{L-} set to substantially the same resistance, the output differential voltage signal outp/outn produces an output common mode voltage vcm_out at an output common mode node between the load resistors R_{L+} and R_{L-}. The differential amplifier 575 includes a first (e.g., negative) input coupled to the output common mode node to receive the output common mode voltage vcm_out. The differential amplifier 575 includes a second (e.g., positive) input configured to receive a reference voltage. Through negative feedback, the differential amplifier 575 is configured to generate the output common mode feedback signal vcmfb to force the output common mode voltage vcm_out to be substantially equal to the reference voltage Vref.

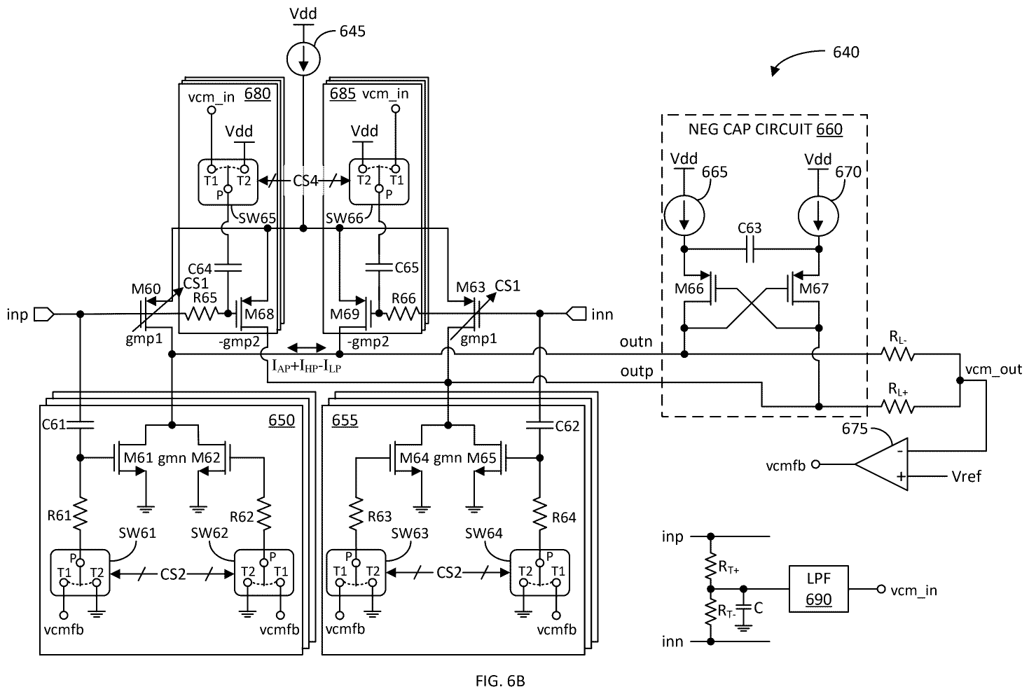

FIG. 6A illustrates a block diagram of another example continuous time linear equalizer (CTLE) 600 in accordance with another aspect of the disclosure. Similarly, the CTLE 600 may employ a single amplification stage, which may result in less power consumption compared to the two-stage implementation of the CTLE 300. Similar to CTLEs 440 and 540, the CTLE 600 need not include inductors, which may have the benefits of less electromagnetic coupling, improved component isolation, smaller IC footprint, and lower signal jitter and ringing. Similar to CTLEs 440 and 540, the CTLE 600 employs current-reuse to effectuate the control of the transfer function or frequency response of the CTLE 600 to achieve Nyquist peaking. Further, similar, but in a different manner, as CTLE 540, the CTLE 600 also employs current stealing to achieve additional Nyquist peaking.

In particular, the CTLE 600 includes a frequency “all-pass” transconductance gain circuit including a transconductance gain gmp component 605, associated with a first set of one or more PFETs, coupled between an input configured to receive an input voltage signal vin and an output current summing node 630. The transconductance gain gmp1 component 605 is configured to generate an “all-pass” current signal component I_{AP} based on the input voltage signal vin. Similarly, the frequency “all-pass” means that the frequency response is substantially flat across the operating frequency range of the CTLE 600 (e.g., up to at least the Nyquist frequency). The transconductance gain gmp1 component 605 may be made programmable or variable for controlling the overall transfer function or frequency response of the CTLE 600.

The CTLE 600 further includes a frequency “high-pass” transconductance gain circuit including a high-pass filter (HPF) 610 and a transconductance gain gmn component 615, associated with one or more NFETs, coupled between the input and the output current summing node 630. The transconductance gain gmn component 615 is configured to generate a “high-pass” current signal component I_{HP} based on the input voltage signal vin. The frequency “high-pass” means that the frequency response exhibits a high-pass frequency response with peaking or pole(s) occurring substantially at the Nyquist frequency. The transconductance gain gmn component 615 may be made programmable or variable for controlling the overall transfer function or frequency response of the CTLE 600, as discussed with reference to CTLE 540. Similar to CTLE 600, the high-pass transconductance gain gmn component 615 reuses the current of the all-pass transconductance gain gmp1 605 to effectuate the high-pass transconductance gain gmn.

The CTLE 600 further includes a frequency “negative low-pass” transconductance gain circuit including a low-pass filter (LPF) 620 and a negative transconductance gain −gmp2 component 625, associated with a second set of one or more PFETs, coupled between the input and the output current summing node 630. The negative transconductance gain gmp2 component 625 is configured to generate a negative low-pass current signal component −I_{LP} based on the input voltage signal vin. Similarly, the frequency “low-pass” means that the frequency response exhibits a low-pass frequency response with a pole(s) occurring below the Nyquist frequency. The negative transconductance gain −gmp2 component 625 may be made programmable or variable for controlling the overall transfer function or frequency response of the CTLE 600, as discussed further herein. As discussed in more detail herein, the negative low-pass transconductance gain −gmp2 component 625 steals current from the all-pass transconductance gain gmp1 605 to effectuate the negative low-pass transconductance gain −gmp2.

The output current summing node 630 is configured to sum the all-pass current signal I_{AP} with the high-pass current signal I_{HP} and the negative low-pass current signal −I_{LP} to generate an output current I_{AP}+I_{HP}−I_{LP} that flows through a load resistor R_{L} to generate an output voltage vout. By programming or varying the high-pass and negative low-pass path transconductance gains gmn and −gmp2 with respect to the all-pass path transconductance gain gmp1 and/or vice-versa, the transfer function or frequency response of the CTLE 600 may be controlled to achieve the desired Nyquist frequency peaking to compensate the input voltage signal vin for high frequency losses incurred while propagating via a data communication channel.

FIG. 6B illustrates a schematic diagram another example continuous time linear equalizer (CTLE) 640 in accordance with another aspect of the disclosure. The CTLE 640 is similar to CTLE 440, including many of the same/similar elements as indicated by the same reference indicators/numbers with the most significant digit being a “6” in CTLE 640 instead of a “4” in CTLE 440. For instance, the CTLE 640 includes input differential PFETs M60/M63, p-side/n-side high-pass transconductance circuits 650 and 655, load resistors R_{L+} and R_{L-}, differential amplifier 675, and optional negative capacitance circuit 660 in the same/similar arrangement as the corresponding components in CTLE 440.

As previously discussed, the input differential PFETs M60/M63 are configured to amplify an input differential signal inp/inn with an all-pass transconductance gain gmp1 to generate an all-pass differential current signal I_{AP}. Similar to input differential PFETs M60/M63, the all-pass transconductance gain gmp1 may be programmable and controlled by a first control signal (CS1) (e.g., by enabling j of a set of M parallel input differential PFETs M60/M63). The p-side/n-side high-pass transconductance circuits 650/655 may be implemented similar to p-side/n-side high-pass transconductance circuits 450/455 previously discussed. As such, the p-side/n-side high-pass transconductance circuits 650/655 may be configured to amplify the input differential signal inp/inn with a high-pass transconductance gain gmn to generate a high-pass differential current signal I_{HP}. Similarly, the high-pass transconductance gain gmn may be programmable based on a second control signal (CS2) (e.g., by enabling k of a set of N parallel slices of the p-side/n-side high-pass transconductance circuits 650/655).

The CTLE 640 further includes p-side/n-side negative low-pass transconductance circuits 680 and 685. As discussed further herein, the p-side/n-side negative low-pass transconductance circuits 680 and 685 steal current from the input differential PFETs M60 and M63 to effectuate a negative low-pass transconductance gain −gmp2 to generate a negative differential low-pass current signal −I_{LP} based on the input differential signal inp/inn, respectively. The negative low-pass transconductance gain −gmp2 may be programmable based on a fourth control signal (CS4) (e.g., enabling i of a set of S parallel slices of the second p-side/n-side negative low-pass transconductance circuits 680 and 685). As discussed further herein, the p-side/n-side negative low-pass transconductance circuits 680 and 685 may be activated/enabled after maximum Nyquist peaking has been exhausted using the N slices of the p-side/n-side high-pass transconductance circuits 650 and 655.

The p-side negative low-pass transconductance circuit 680 includes a PFET M68, a low-pass filter (LPF) including a resistor R65 and capacitor C64, and a switching device SW65. The PFET M68 is coupled between the current source 645 and the p-side differential output outp of the CTLE 640. The LPF is coupled between the gate of the p-side input differential PFET M60 and a gate of the PFET M68. More specifically, the resistor R65 and the capacitor C64 of the LPF are coupled in series between the gate of the p-side input differential PFET M60 and the switching device SW65, wherein an output node of the LPF, situated between the resistor R65 and capacitor C64, is coupled to the gate of PFET M68. The switching device SW65 may be implemented as a SPDT switching device including a pole (P) coupled to the capacitor C64, a first throw (T1) coupled to an output of the low-pass filter (LPF) 690 to receive the input common mode voltage vcm_in therefrom, and a second throw (T2) coupled to the upper voltage rail Vdd. The state (e.g., whether the pole (P) is coupled to the first throw (T1) or the second throw (T2)) of the SPDT switching device SW65 is controlled by the fourth control signal (CS4).

As mentioned, the CTLE 640 may include a set of S parallel instantiations or slices of the p-side differential negative low-pass transconductance gain circuits 680, where S is an integer. The switching device SW65, operating as a control circuit, is configured via the fourth control signal CS4 to couple the pole (P) to the first throw (T1) to disable the corresponding slice of the p-side negative low-pass transconductance circuit 680 by coupling the upper voltage rail (or applying) Vdd to the gate of the PFET M68. Similarly, the switching device SW65 is configured, via the fourth control signal CS4, to couple the pole (P) to the second throw (T2) to enable the corresponding slice of the p-side negative low-pass transconductance circuit 680 by coupling the output of the LPF 690 (or applying vcm_in) to the gate of the PFET M68.

The n-side negative low-pass transconductance circuit 685 includes a PFET M69, a low-pass filter (LPF) including resistor R66 and capacitor C65, and a switching device SW66. The PFET M69 is coupled between the current source 645 and the n-side differential output outn of the CTLE 640. The LPF is coupled between the gate of the n-side input differential PFET M63 and a gate of the PFET M69. More specifically, the resistor R66 and capacitor C65 of the LPF are coupled in series between the gate of the n-side input differential PFET M63 and the switching device SW66, wherein an output node of the LPF, situated between the resistor R66 and the capacitor C65, is coupled to the gate of PFET M69. The switching device SW66 may be implemented as a SPDT switching device including a pole (P) coupled to the capacitor C65, a first throw (T1) coupled to the output of the LPF 690 to receive the input common mode voltage vcm_in therefrom, and a second throw (T2) coupled to the upper voltage rail Vdd. The state (e.g., whether the pole (P) is coupled to the first throw (T1) or the second throw (T2)) of the SPDT switching device SW66 is controlled by the fourth control signal (CS4).

As mentioned, the CTLE 640 may include a set of S parallel instantiations or slices of the n-side negative low-pass transconductance gain circuits 685, where S is an integer. The switching device SW66, operating as a control circuit, is configured via the fourth control signal CS4 to couple the pole (P) to the first throw (T1) to disable the corresponding slice of the n-side negative low-pass transconductance circuit 685 by coupling the upper voltage rail (or applying) Vdd to the gate of the PFET M69. Similarly, the switching device SW66 is configured, via the fourth control signal CS4, to couple the pole (P) to the second throw (T2) to enable the corresponding slice of the n-side negative low-pass transconductance circuit 685 by coupling the output of the LPF 690 (or applying vcm_in) to the gate of the PFET M69.

The degree of Nyquist peaking with respect to the low frequency zero of the transfer function or frequency response of the CTLE 640 depends on how many of the S slices of the p-side/n-side negative low-pass transconductance gain circuits 680/685 are enabled. For example, if all of the S slices of the p-side/n-side negative low-pass transconductance gain circuits 680/685 are disabled, the CTLE 640 has a transfer function or frequency response dictated by the all-pass transconductance gain gmp of the input differential PFETs M60 and M63 and the high-pass transconductance gain gmn of the p-side/n-side high-pass transconductance circuits 650/655. In such case, the current signal generated by the CTLE 640 is substantially the current signal I_{AP}+I_{HP} (e.g., the negative low-pass current signal I_{LP} may be substantially zero (0)).

If all of the S slices of the p-side/n-side negative low-pass transconductance gain circuits 680 and 685 are enabled, the CTLE 640 has a transfer function or frequency response with a maximum Nyquist peaking with respect to the low frequency zero dictated by the maximum effective negative low-pass transconductance gain gmp2, the maximum effective high-pass transconductance gain of the p-side/n-side high-pass transconductance gain circuits 650/655, and the all-pass transconductance gain gmp1 of the input differential PFETs M60 and M63. In such case, the current signal generated by the CTLE 640 may be characterized by a sum of the all-pass current signal I_{AP}, the maximum high-pass current I_{HP}, and the maximum negative low-pass current signal I_{HP,max} (e.g., I_{AP}+I_{HP,max}−I_{LP,max}).

Accordingly, the degree of Nyquist peaking in the transfer function or frequency response of the CTLE 640 depends on the number i of S slices of the p-side/n-side negative low-pass transconductance gain circuits 680 and 685 that are enabled, where i is also an integer equal to or less than S (e.g., i≤S). Thus, if higher Nyquist peaking with respect to the low frequency zero that may be achieved by the p-side/n-side high-pass transconductance circuits 650/655 is desired, set i as desired above zero (0); and if Nyquist peaking as achieved by the p-side/n-side high-pass transconductance circuits 650/655 is satisfactory, set i to be to zero (0). As an example, the CTLE 640 may include a set of S=12 slices of the p-side and n-side negative low-pass transconductance gain circuits 680 and 685 to provide a set of 12 progressive levels of additional Nyquist peaking in the transfer function or frequency response of the CTLE 640 above what can be achieved by the p-side/n-side high-pass transconductance circuits 650/655.

The p-side and n-side negative low-pass transconductance gain circuits 680 and 685 steal all-pass current from the input differential PFETs M60 and M63 to effectuate the negative low-pass transconductance gain −gmp2, and uses some of it (its low-pass frequency (LPF) portion thereof) to further reduce the low frequency zero portion of the transfer function or frequency response of the CTLE 640. As the current source 645 provides a substantially constant current to the input differential PFETs M60 and M63 and the PFETs M68 and M69 of the p-side and n-side negative low-pass transconductance gain circuits 680 and 685, the enabled i slices of the of the p-side and n-side negative low-pass transconductance gain circuits 680 and 685 steal all-pass current from the input differential PFETs M60 and M63 reduces their transconductance gain gmp1. The p-side and n-side negative low-pass transconductance gain circuits 680 and 685 uses an LPF portion of the “stolen” all-pass current to further reduce the low frequency zero portion with respect to the Nyquist frequency portion. Thus, the effect of the p-side and n-side negative low-pass transconductance gain circuits 680 and 685 is to further reduce the lower frequency zero portion of the transfer function or frequency response of the CTLE 640 based on the number i of slices of the p-side and n-side negative low-pass transconductance gain circuits 680 and 685 enabled.

For example, if the positive component inp has a voltage higher than the negative component inn of the input differential voltage signal inp/inn, the input differential PFET M63 is turned on greater than the input differential PFET M60. Thus, the reduced (by stealing) all-pass current I_{AP} flows from the PFET M63 via load resistors R_{L+} and R_{L-} to the NFETs M61 of the N slices of the p-side high-pass transconductance gain circuit 650. As the high frequency content of the higher voltage positive component inp of the input differential signal inp/inn is applied to the gate of the N NFETs M61 via the corresponding N HPFs C61/R61, the high-pass differential current I_{HP} flows from the input differential PFET M63 to the NFETs M61 of the N slices of the p-side high-pass transconductance gain circuits 650 via the positive differential output outp, differential load resistors R_{L+}/R_{L-} and the negative differential output outn.

As the coupling of the drains of PFETs M68/M69 to the differential output outn/outp is opposite to the coupling of the drains of input differential PFETs M60 and M63 to the differential output outp/outn, the stolen LPF current I_{LP} flows from PFET M69 via load resistors R_{L-} and R_{L+} to the NFETs M64 of the N slices of the n-side high-pass transconductance gain circuit 655. In other words, the current I_{LP} flows in a direction opposite to the all-pass current I_{AP} and the high-pass current I_{HP} to effectuate the negative transconductance gain −gmp2.

Similarly, if the positive component inp has a voltage lower than the negative component inn of the input differential voltage signal inp/inn, the input differential PFET M60 is turned on greater than the input differential PFET M63. Thus, the reduced (by stealing) all-pass current I_{AP} flows from the PFET M60 via load resistors R_{L-} and R_{L+} to the NFETs M65 of the N slices of the n-side high-pass transconductance gain circuit 655. As the high frequency content of the higher voltage negative component inn of the input differential signal inp/inn is applied to the gate of N NFETs M65 via the corresponding N HPFs C62/R64, the high-pass differential current I_{HP} flows from the input differential PFET M60 to the NFETs M65 of the N slices of the n-side high-pass transconductance gain circuits 655 via the negative differential output outn, differential load resistors R_{L-}/R_{L+} and the positive differential output outp.

Again, as the coupling of the drains of PFETs M68/M69 to the differential output outn/outp is opposite to the coupling of the drains of input differential PFETs M60 and M63 to the differential output outp/outn, the stolen LPF current I_{LP} flows from PFET M68 via load resistors R_{L+} and R_{L-} to the NFETs M62 of the N slices of the p-side high-pass transconductance gain circuit 650. In other words, the current I_{LP} flows in a direction opposite the direction of the all-pass current I_{AP} and the high-pass current I_{HP} to effectuate the negative transconductance gain −gmp2.

The current signal I_{AP}+I_{HP}−I_{LP} generated by the CTLE 640 flows through the load resistors R_{L+} and R_{L-} to generate an output differential voltage signal outp/outn at the drains of the input differential PFETs M63 and M60, respectively. With the load resistors R_{L+} and R_{L-} set to substantially the same resistance, the output differential voltage signal outp/outn produces an output common mode voltage vcm_out at an output common mode node between the load resistors R_{L+} and R_{L-}. The differential amplifier 675 includes a first (e.g., negative) input coupled to the output common mode node to receive the output common mode voltage vcm_out. The differential amplifier 675 includes a second (e.g., positive) input configured to receive a reference voltage. Through negative feedback, the differential amplifier 675 is configured to generate the output common mode feedback signal vcmfb to force the output common mode voltage vcm_out to be substantially equal to the reference voltage Vref.

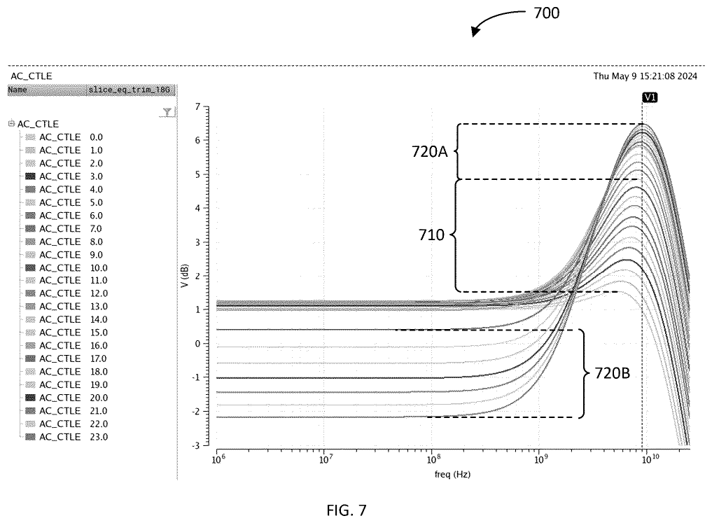

FIG. 7 illustrates a graph depicting a transfer function 700 associated with the example continuous time linear equalizers (CTLEs) 400, 440, 500, 540, 600, and 640 described herein in accordance with another aspect of the disclosure. The horizontal axis of the graph represents frequency in Hertz (Hz) in a logarithm scale from 100 mega Hertz (MHz) (106 Hz) to over 10 giga Hertz (1010 Hz). The vertical axis of the graph represents CTLE gain (V) in decibel (dB) in a linear scale from −3 dB to 7 dB.

As noted, the Nyquist frequency is at substantially 9.9 GHZ as indicated by a dashed vertical line. The high-pass transfer function or frequency response effectuated by the high-pass transconductance gain components 410/415, 510/515, 610/615 and the corresponding p-side/n-side high-pass transconductance gain circuits 450/455, 550/555, and 650/655 may provide a first set of 12 progressive levels of Nyquist peaking 710. The high-pass transfer function or frequency response effectuated by the second high-pass transconductance gain circuits 520/525 and the corresponding second p-side/n-side high-pass transconductance gain circuits 580/585, as well as the negative low-pass transconductance gain circuits 620/625 and the corresponding p-side/n-side negative low-pass transconductance circuits 680/685 may provide a second set of 12 progressive levels of Nyquist peaking 720A.

Note that a subset of seven (7) of the second set of secondary set of 12 progressive levels of Nyquist peaking 720B are associated with low frequency zero significantly and progressively lower than those associated with the first set of progressive levels of Nyquist peaking 710 and a subset of five (5) of the second set of 12 progressive levels Nyquist peaking 720A. These progressively lower low frequency zero are attributed to the current stealing of the second p-side/n-side high-pass transconductance circuits 580/585 or the current stealing/negative low-pass transconductance of the p-side/n-side negative low-pass transconductance circuits 680/685 previously discussed. Accordingly, the CTLEs 400, 440, 500, 540, 600, and 640 have significant flexibility in achieving a desired transfer function or frequency response to compensate for high frequency losses incurred by the input voltage signal due to propagation across a data communication channel.

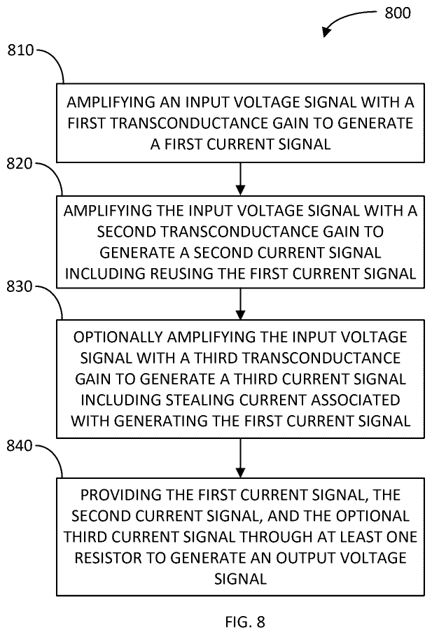

FIG. 8 illustrates a flow diagram of an example method 800 of equalizing an input voltage signal in accordance with another aspect of the disclosure. The method 800 includes amplifying an input voltage signal with a first transconductance gain to generate a first current signal (block 810). Examples of means for amplifying an input voltage signal with a first transconductance gain to generate a first current signal include any of the all-pass transconductance gain components 405, 505, 605, and input differential PFETs M40/M43, M50/M53, and M60/M63.

The method 800 further includes amplifying the input voltage signal with a second transconductance gain to generate a second current signal including reusing the first output current signal (block 820). Examples of means for amplifying the input voltage signal with a second transconductance gain to generate a second current signal including reusing the first current signal include any of the high-pass transconductance gain gmn components 515 and 615, and p-side/n-side high-pass transconductance gain circuits 550/555 and 650/655.

The method 800 further includes optionally amplifying the input voltage signal with a third transconductance gain to generate a third current signal including stealing current associated with generating the first current signal (block 830). Examples of means for optionally amplifying the input voltage signal with a third transconductance gain to generate a third current signal including stealing current associated with generating the first current signal include any of the transconductance gain components 525 and 625, second p-side/n-side high-pass transconductance gain circuits 580/585, and p-side/n-side negative low-pass transconductance gain circuits 680/685.

Additionally, the method 800 includes providing the first current signal, the second current signal, and the optional third current signal through at least one resistor to generate an output voltage signal (block 840). Examples of means for providing the first current signal, the second current signal, and the optional third current signal through at least one resistor to generate an output voltage signal include any of the output current summing nodes 430, 530, and 630 coupled to corresponding load resistors, or any of the differential outputs outp/outn coupled to differential load resistors R_{L+}/R_{L-} of the CTLEs 440, 540, and 640.

The following provides an overview of aspects of the present disclosure:

Aspect 1: A continuous time linear equalizer (CTLE), comprising: a first transconductance gain circuit configured to amplify an input voltage signal with a first transconductance gain to generate a first current signal; a second transconductance gain circuit configured to amplify the input voltage signal with a second transconductance gain to generate a second current signal, wherein the second transconductance gain circuit is configured to reuse the first current signal to generate the second current signal; and at least one resistor through which the first current signal and the second current signal flow to generate an output voltage signal.

Aspect 2: The CTLE of aspect 1, wherein the first transconductance gain circuit is configured to generate the first current signal with a transfer function that is substantially flat up to at least a Nyquist frequency associated with the input voltage signal.

Aspect 3: The CTLE of aspect 1 or 2, wherein the second transconductance gain circuit is configured to generate the second current signal with a transfer function that has a high-pass frequency response with peaking substantially at a Nyquist frequency associated with the input voltage signal.

Aspect 4: The CTLE of aspect 1 or 2, wherein the second transconductance gain circuit is configured to generate the second current signal with a transfer function that has a high-pass frequency response with a selected one of a set of progressive levels of peaking substantially at a Nyquist frequency associated with the input voltage signal.

Aspect 5: The CTLE of any one of aspects 1-4, wherein the input voltage signal, the first current signal, the second current signal, and the output voltage signal comprise an input differential voltage signal, a first differential current signal, a second differential current signal, and an output differential voltage signal, respectively.

Aspect 6: The CTLE of aspect 5, wherein: the first transconductance gain circuit comprises a first p-channel field effect transistor (PFET) and a second PFET including gates configured to receive positive and negative components of the input differential voltage signal, respectively; and the second transconductance gain circuit comprises: a p-side high-pass transconductance gain circuit, comprising: a first n-channel field effect transistor (NFET) including a drain coupled to a drain of the first PFET; and a first high-pass filter (HPF) coupled between the gate of the first PFET and a gate of the first NFET; and an n-side high-pass transconductance gain circuit, comprising: a second NFET including a drain coupled to a drain of the second PFET; and a second HPF coupled between the gate of the second PFET and a gate of the second NFET.

Aspect 7: The CTLE of aspect 6, wherein: the p-side high-pass transconductance gain circuit further comprises: a third NFET including a drain coupled to the drain of the first PFET, and a source coupled to a source of the first NFET, wherein the sources of the first and third NFETs are coupled to the lower voltage rail; and a first control circuit configured to: enable/disable: the first NFET based on a control signal; and disable/enable the third NFET based on the control signal, respectively; the n-side high-pass transconductance gain circuit further comprises: a fourth NFET including a drain coupled to the drain of the second PFET, and a source coupled to a source of the second NFET, wherein the sources of the second and fourth NFETs are coupled to the lower voltage rail; and a second control circuit configured to: enable/disable the second NFET based on the control signal; and disable/enable the fourth NFET based on the control signal, respectively.

Aspect 8: The CTLE of aspect 7, wherein the CTLE comprises: a set of N slices of the p-side high-pass transconductance gain circuit, wherein N is an integer; and a set of N slices of the n-side high-pass transconductance gain circuit.

Aspect 9: The CTLE of aspects 7 or 8, wherein the at least one resistor comprises first and second resistors coupled in series between the drain of the first PFET and the drain of the second NFET, and wherein the first and second current signals are configured to flow between the drains of the first and second PFETs through the first and second resistors to generate the output differential voltage signal across the drains of the first and second PFETs, respectively.

Aspect 10: The CTLE of aspect 9, further comprising a differential amplifier including a first input coupled to a node between the first and second resistors, a second input configured to receive a reference voltage, and an output configured to generate an output common mode feedback signal.

Aspect 11: The CTLE of aspect 10, wherein: the first control circuit is configured to: enable/disable the first NFET including coupling the output of the differential amplifier/the lower voltage rail to the gate of the first NFET, respectively; and disable/enable the third NFET including coupling the lower voltage rail/the output of the differential amplifier to the gate of the third NFET, respectively; and the second control circuit is configured to: enable/disable the second NFET including coupling the output of the differential amplifier/the lower voltage rail to the gate of the second NFET, respectively; and disable/enable the fourth NFET including coupling the lower voltage rail/the output of the differential amplifier to the gate of the fourth NFET, respectively.

Aspect 12: The CTLE of any one of aspects 1-11, further comprising a third transconductance gain circuit configured to amplify the input voltage signal with a third transconductance gain to generate a third current signal, wherein the third transconductance gain circuit is configured to steal current from the first transconductance gain circuit to generate the third current signal, and wherein the third current signal is configured to flow through the at least one resistor to generate the output voltage signal.

Aspect 13: The CTLE of aspect 12, wherein the third transconductance gain circuit is configured to generate the second current signal with a transfer function that has a high-pass frequency response with peaking substantially at a Nyquist frequency associated with the input voltage signal.

Aspect 14: The CTLE of aspect 12 or 13, wherein the input voltage signal, the first current signal, the second current signal, the third current signal, and the output voltage signal comprise an input differential voltage signal, a first differential current signal, a second differential current signal, a third differential current signal, and an output differential voltage signal, respectively.

Aspect 15: The CTLE of aspect 14, wherein: the first transconductance gain circuit comprises a first p-channel field effect transistor (PFET) and a second PFET including gates configured to receive positive and negative components of the input differential voltage signal, respectively; and the third transconductance gain circuit comprises: a p-side high-pass transconductance gain circuit comprising: a third PFET including source and drain coupled to source and drain of the first PFET, respectively; a first high-pass filter (HPF) coupled between the gate of the first PFET and a gate of the third PFET; and an n-side high-pass transconductance gain circuit comprising: a fourth PFET including source and drain coupled to source and drain of the second PFET, respectively; and a second HPF coupled between the gate of the second PFET and a gate of the fourth PFET.

Aspect 16: The CTLE of aspect 15, wherein: the p-side high-pass transconductance gain circuit further comprises a first control circuit configured to enable/disable the third PFET based on a control signal; and the n-side high-pass transconductance gain circuit further comprises a second control circuit configured to enable/disable the fourth PFET based on the control signal.

Aspect 17: The CTLE of aspect 16, wherein the CTLE further comprises: a set of P slices of the p-side high-pass transconductance gain circuit, wherein P is an integer; and a set of P slices of the n-side high-pass transconductance gain circuit.

Aspect 18: The CTLE of any one of aspects 14-17, wherein: the first transconductance gain circuit comprises a first p-channel field effect transistor (PFET) and a second PFET including gates configured to receive positive and negative components of the input differential voltage signal, respectively; and the third transconductance gain circuit comprises: a p-side negative low-pass transconductance gain circuit comprising: a third PFET including source and drain coupled to source and drain of the second PFET, respectively; a first low-pass filter (LPF) coupled between the gate of the first PFET and a gate of the third PFET; and an n-side negative low-pass transconductance gain circuit comprising: a fourth PFET including source and drain coupled to source and drain of the first PFET, respectively; and a second LPF coupled between the gate of the second PFET and a gate of the fourth PFET.

Aspect 19: The CTLE of aspect 18, wherein: the p-side negative low-pass transconductance gain circuit further comprises a first control circuit configured to enable/disable the third PFET based on a control signal; and the n-side negative low-pass transconductance gain circuit further comprises a second control circuit configured to enable/disable the fourth PFET based on the control signal.

Aspect 20: The CTLE of aspect 19, wherein the CTLE further comprises: a set of S slices of the p-side negative low-pass transconductance gain circuit, wherein S is an integer; and a set of S slices of the n-side negative low-pass transconductance gain circuit.

Aspect 21: A method of equalizing an input voltage signal, comprising: amplifying an input voltage signal with a first transconductance gain to generate a first current signal; amplifying the input voltage signal with a second transconductance gain to generate a second current signal including reusing the first current signal; providing the first current signal and the second current signal through at least one resistor to generate an output voltage signal.

Aspect 22: The method of aspect 21, further comprising: amplifying the input voltage signal with a third transconductance gain to generate a third current signal including stealing current associated with generating the first current signal; and providing the third current signal through the at least one resistor to generate the output voltage signal.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples described herein but is to be accorded the widest scope consistent with the principles and novel features disclosed herein.

What is claimed:

1. A continuous time linear equalizer (CTLE), comprising:
a first transconductance gain circuit configured to amplify an input voltage signal with a first transconductance gain to generate a first current signal;
a second transconductance gain circuit configured to amplify the input voltage signal to generate a second transconductance gain with a second current signal, wherein the second transconductance gain circuit is configured to reuse the first current signal to generate the second current signal; and
at least one resistor through which the first current signal and the second current signal flow to generate an output voltage signal.

2. The CTLE of claim 1, wherein the first transconductance gain circuit is configured to generate the first current signal with a transfer function that is substantially flat up to at least a Nyquist frequency associated with the input voltage signal.

3. The CTLE of claim 1, wherein the second transconductance gain circuit is configured to generate the second current signal with a transfer function that has a high-pass frequency response with peaking substantially at a Nyquist frequency associated with the input voltage signal.

4. The CTLE of claim 1, wherein the second transconductance gain circuit is configured to generate the second current signal with a transfer function that has a high-pass frequency response with a selected one of a set of progressive levels of peaking substantially at a Nyquist frequency associated with the input voltage signal.

5. The CTLE of claim 1, wherein the input voltage signal, the first current signal, the second current signal, and the output voltage signal comprise an input differential voltage signal, a first differential current signal, a second differential current signal, and an output differential voltage signal, respectively.

6. The CTLE of claim 5, wherein:
the first transconductance gain circuit comprises a first p-channel field effect transistor (PFET) and a second PFET including gates configured to receive positive and negative components of the input differential voltage signal, respectively; and
the second transconductance gain circuit comprises:
a p-side high-pass transconductance gain circuit, comprising:
a first n-channel field effect transistor (NFET) including a drain coupled to a drain of the first PFET; and
a first high-pass filter (HPF) coupled between the gate of the first PFET and a gate of the first NFET; and
an n-side high-pass transconductance gain circuit, comprising:
a second NFET including a drain coupled to a drain of the second PFET; and
a second HPF coupled between the gate of the second PFET and a gate of the second NFET.

7. The CTLE of claim 6, wherein:
the p-side high-pass transconductance gain circuit further comprises:
a third NFET including a drain coupled to the drain of the first PFET, and a source coupled to a source of the first NFET, wherein the sources of the first and third NFETs are coupled to a lower voltage rail; and
a first control circuit configured to:
enable/disable the first NFET based on a control signal; and
disable/enable the third NFET based on the control signal respectively;
the n-side high-pass transconductance gain circuit further comprises:
a fourth NFET including a drain coupled to the drain of the second PFET, and a source coupled to a source of the second NFET, wherein the sources of the second and fourth NFETs are coupled to the lower voltage rail; and
a second control circuit configured to:
enable/disable the second NFET based on the control signal; and
disable/enable the fourth NFET based on the control signal respectively.

8. The CTLE of claim 7, wherein the CTLE comprises:
a set of N slices of the p-side high-pass transconductance gain circuit, wherein N is an integer; and
a set of N slices of the n-side high-pass transconductance gain circuit.

9. The CTLE of claim 7, wherein the at least one resistor comprises first and second resistors coupled in series between the drain of the first PFET and the drain of the second NFET, and wherein the first and second current signals are configured to flow between the drains of the first and second PFETs through the first and second resistors to generate the output differential voltage signal across the drains of the first and second PFETs, respectively.

10. The CTLE of claim 9, further comprising a differential amplifier including a first input coupled to a node between the first and second resistors, a second input configured to receive a reference voltage, and an output configured to generate an output common mode feedback signal.

11. The CTLE of claim 10, wherein:
the first control circuit is configured to:
enable/disable the first NFET including coupling the output of the differential amplifier/the lower voltage rail to the gate of the first NFET based on the control signal, respectively; and
disable/enable the third NFET including coupling the lower voltage rail/output of the differential amplifier to the gate of the third NFET based on the control signal, respectively; and
the second control circuit is configured to:
enable/disable the second NFET including coupling the output of the differential amplifier/the lower voltage rail to the gate of the second NFET based on the control signal, respectively; and
disable/enable the fourth NFET including coupling the lower voltage rail/output of the differential amplifier to the gate of the fourth NFET based on the control signal, respectively.

12. The CTLE of claim 1, further comprising a third transconductance gain circuit configured to amplify the input voltage signal with a third transconductance gain to generate a third current signal, wherein the third transconductance gain circuit is configured to steal current from the first transconductance gain circuit to generate the third current signal, and wherein the third current signal is configured to flow through the at least one resistor to generate the output voltage signal.

13. The CTLE of claim 12, wherein the third transconductance gain circuit is configured to generate the second current signal with a transfer function that has a high-pass frequency response with peaking substantially at a Nyquist frequency associated with the input voltage signal.

14. The CTLE of claim 12, wherein the input voltage signal, the first current signal, the second current signal, the third current signal, and the output voltage signal comprise an input differential voltage signal, a first differential current signal, a second differential current signal, a third differential current signal, and an output differential voltage signal, respectively.

15. The CTLE of claim 14, wherein:
the first transconductance gain circuit comprises a first p-channel field effect transistor (PFET) and a second PFET including gates configured to receive positive and negative components of the input differential voltage signal, respectively; and
the third transconductance gain circuit comprises:
a p-side high-pass transconductance gain circuit comprising:
a third PFET including source and drain coupled to source and drain of the first PFET, respectively;
a first high-pass filter (HPF) coupled between the gate of the first PFET and a gate of the third PFET; and
an n-side high-pass transconductance gain circuit comprising:
a fourth PFET including source and drain coupled to source and drain of the second PFET, respectively; and
a second HPF coupled between the gate of the second PFET and a gate of the fourth PFET.

16. The CTLE of claim 15, wherein:
the p-side high-pass transconductance gain circuit further comprises a first control circuit configured to enable/disable the third PFET based on a control signal; and
the n-side high-pass transconductance gain circuit further comprises a second control circuit configured to enable/disable the fourth PFET based on the control signal.

17. The CTLE of claim 16, wherein the CTLE further comprises:
a set of P slices of the p-side high-pass transconductance gain circuit, wherein P is an integer; and
a set of P slices of the n-side high-pass transconductance gain circuit.

18. The CTLE of claim 14, wherein:
the first transconductance gain circuit comprises a first p-channel field effect transistor (PFET) and a second PFET including gates configured to receive positive and negative components of the input differential voltage signal, respectively; and
the third transconductance gain circuit comprises:
a p-side negative low-pass transconductance gain circuit comprising:
a third PFET including source and drain coupled to source and drain of the second PFET, respectively;
a first low-pass filter (LPF) coupled between the gate of the first PFET and a gate of the third PFET; and
an n-side negative low-pass transconductance gain circuit comprising:
a fourth PFET including source and drain coupled to source and drain of the first PFET, respectively; and
a second LPF coupled between the gate of the second PFET and a gate of the fourth PFET.

19. The CTLE of claim 18, wherein:
the p-side negative low-pass transconductance gain circuit further comprises a first control circuit configured to enable/disable the third PFET based on a control signal; and
the n-side negative low-pass transconductance gain circuit further comprises a second control circuit configured to enable/disable the fourth PFET based on the control signal.

20. The CTLE of claim 19, wherein the CTLE further comprises:
a set of S slices of the p-side negative low-pass transconductance gain circuit, wherein S is an integer; and
a set of S slices of the n-side negative low-pass transconductance gain circuit.
